(19) United States
(12) Patent Application Publication
(10) Pub. No.: US 2025/0022963 A1
(43) Pub. Date: Jan. 16, 2025

(54) THIN FILM TRANSISTOR HAVING SPINEL SINGLE-PHASE CRYSTALLINE IZTO OXIDE SEMICONDUCTOR

(71) Applicant: IUCF-HYU (INDUSTRY-UNIVERSITY COOPERATION FOUNDATION HANYANG UNIVERSITY), Seoul (KR)

(72) Inventors: Jae Kyeong JEONG, Seoul (KR); Gwang Bok KIM, Seoul (KR)

(21) Appl. No.: 18/712,710

(22) PCT Filed: Dec. 6, 2022
(86) PCT No.: PCT/KR2022/019688

§ 371 Date: May 23, 2024

(30) Foreign Application Priority Data
Dec. 6, 2021 (KR) 10-2021-0173205

(51) Int. Cl. H01L 29/786; H01L 29/04; H01L 29/417

(52) U.S. Cl. CPC H01L 29/7869; H01L 29/045; H01L 29/41733; H01L 29/78696

(57) ABSTRACT

A thin film transistor is provided. The thin film transistor comprises a gate electrode, an In—Zn—Sn oxide (IZTO) channel layer that overlaps the top or bottom of the gate electrode and has a spinel single-phase crystalline, a gate insulating layer disposed between the gate electrode and the IZTO channel layer, and source and drain electrodes respectively connected to both ends of the IZTO channel layer.

### TECHNICAL FIELD

The present invention relates to semiconductor devices, and specifically to a transistor having an oxide semiconductor layer.

### BACKGROUND ART

As a silicon film used as a semiconductor film of a transistor, an amorphous silicon film or a polycrystalline silicon film is used depending on the purpose. For example, in the case of a transistor included in a large display device, it is desirable to use an amorphous silicon film that can be formed with relatively uniform characteristics even if it is formed in a large area. On the other hand, in the case of devices including driving circuits, etc., it is desirable to use a polycrystalline silicon film that can exhibit high field-effect mobility. As a method for forming the polycrystalline silicon film, there is a known method of heating the amorphous silicon film at high temperature or treating it with laser light.

Recently, research is being conducted on using oxide semiconductors as a channel layer for transistors (JP Publication 2006-165528). In relation to this, it is known that the polycrystalline oxide semiconductor layer can exhibit excellent electrical properties compared to the amorphous oxide semiconductor layer, but the characteristics of the polycrystalline oxide semiconductor layer are not uniform at various locations in the substrate compared to the amorphous oxide semiconductor layer, which acts as an obstacle in commercializing the polycrystalline oxide semiconductor layer.

### DISCLOSURE

### Technical Problem

The problem to be solved by the present invention is to provide a thin film transistor including an oxide semiconductor thin film that not only exhibits high field-effect mobility but also has uniform characteristics.

The technical problems of the present invention are not limited to the technical problems mentioned above, and other technical problems not mentioned will be clearly understood by those skilled in the art from the description below.

### Technical Solution

One aspect of the invention provides a thin film transistor. The thin film transistor comprises a gate electrode, an In—Zn—Sn oxide (IZTO) channel layer that overlaps the top or bottom of the gate electrode and has a spinel single-phase crystalline, a gate insulating layer disposed between the gate electrode and the IZTO channel layer, and source and drain electrodes respectively connected to both ends of the IZTO channel layer.

The IZTO channel layer may include a plurality of crystal grains having the same spinel crystal phase with different crystal directions. The IZTO channel layer may have a composition of Zn₂₋ₓSn₁₋ₓIn₂ₓO₄ (0<x<0.45). The x may be 0.3 to 0.36. Specifically, the x may be 0.33. The IZTO channel layer may have crystal planes of (220), (222), (331), and (422).

One aspect of the invention provides a thin film transistor. The thin film transistor comprises a gate electrode, an IZTO (In—Zn—Sn oxide) channel layer that overlaps the gate electrode and has a plurality of crystal grains, where all the crystal grains have a composition of Zn₂₋ₓSn₁₋ₓIn₂ₓO₄ (0<x<0.45), a gate insulating layer disposed between the gate electrode and the IZTO channel layer, and source and drain electrodes respectively connected to both ends of the IZTO channel layer.

The crystal grains may have different crystal directions. The x may be 0.3 to 0.36. Specifically, the x may be 0.33. The IZTO channel layer may have crystal planes of (220), (222), (331), and (422).

### Advantageous Effects

According to embodiments of the present invention, it is possible to provide a thin film transistor including a crystalline oxide semiconductor thin film that exhibits high field-effect mobility and excellent distribution of electrical properties.

However, the effects of the present invention are not limited to the effects mentioned above, and other effects not mentioned will be clearly understood by those skilled in the art from the description below.

### DESCRIPTION OF DRAWINGS

FIG. 1 is a cross-sectional view showing a thin film transistor according to an embodiment of the present invention.

FIG. 2 is a cross-sectional view showing a method of manufacturing a thin film transistor according to another embodiment of the present invention.

FIGS. 3 and 4 are cross-sectional views showing a method of manufacturing a thin film transistor according to another embodiment of the present invention.

FIG. 5 is a graph showing the composition of the metal oxide thin films obtained from Metal Oxide Thin Film Preparation Examples 1 to 3 according to gas flow conditions during sputtering.

FIG. 6 is a graph showing XRD patterns of metal oxide thin films according to Metal Oxide Thin Film Preparation Examples 4 to 7.

FIG. 7 is a graph showing XRD patterns of IZTO semiconductor patterns included in TFTs manufactured in TFT Preparation Examples 1 to 5.

FIG. 8 is a TEM (Transmission Electron Microscope) image of a cross-section of the IZTO semiconductor pattern included in the TFT manufactured in TFT Preparation Example 1.

FIG. 9 is a graph showing the transfer characteristics of the TFT manufactured in TFT Preparation Example 1.

FIGS. 10, 11, and 12 are graphs showing the distribution of mobility, SS, and threshold voltage of TFTs according to TFT Preparation Example 1 and TFT Preparation Example 3, respectively.

FIGS. 13 and 14 show the transfer characteristics of the TFT according to TFT Preparation Example 3 under positive gate bias stress (PBS) conditions and under negative gate bias stress (NBS) conditions, respectively.

FIGS. 15 and 16 show the transfer characteristics of the TFT according to TFT Preparation Example 1 under positive gate bias stress (PBS) conditions and under negative gate bias stress (NBS) conditions, respectively.

### MODES OF THE INVENTION

Hereinafter, in order to explain the present invention in more detail, preferred embodiments according to the present invention will be described in more detail with reference to the attached drawings. However, the present invention is not limited to the embodiments described herein and may be embodied in other forms. In the drawings, where a layer is referred to as being “on” another layer or substrate, it may be formed directly on the other layer or substrate, or there may be a third layer interposed between them.

### Thin Film Transistor

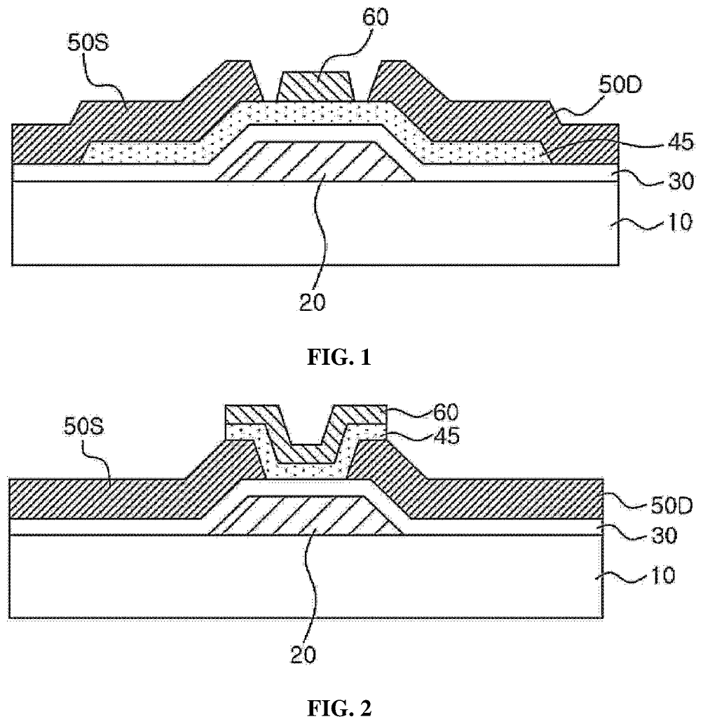

FIG. 1 is a cross-sectional view showing a thin film transistor according to an embodiment of the present invention.

Referring to FIG. 1, a substrate 10 may be provided. Substrate 10 may be a semiconductor, metal, glass or polymer substrate. In one example, the substrate 10 may be a semiconductor or metal substrate. An insulating barrier layer (not shown) may be formed on the substrate 10. In one example, the substrate 10 may be a silicon substrate, and the insulating barrier layer may be silicon oxide.

A gate electrode 20 extending in one direction may be formed on the substrate 10. The gate electrode 20 may be formed using Al, Cr, Cu, Ta, Ti, Mo, W, or an alloy thereof. A gate insulating layer 30 may be formed on the gate electrode 20. The gate insulating layer 30 is a silicon oxide layer, for example, SiO₂; a silicon oxynitride layer (SiON); an aluminum oxynitride layer; a high-k insulating layer with a higher dielectric constant compared to a silicon oxide layer; or a composite layer thereof. An example of the high-k insulating layer with a higher dielectric constant than a silicon oxide layer may be Al₂O₃, HfO₂, or ZrO₂.

An indium-zinc-tin oxide layer (In—Zn—Sn oxide, hereinafter referred to as IZTO) disposed to overlap the gate electrode 20 may be formed on the gate insulating layer 30 as a channel layer 45. The IZTO channel layer 45 may be formed by deposition using a physical vapor deposition method such as sputtering or a chemical deposition method such as chemical vapor deposition or atomic layer deposition, and then crystallized. The deposition may be a sputtering method using an indium oxide (In₂O₃) target, a zinc oxide (ZnO) target, and a tin oxide (SnO₂) target in an inert gas atmosphere. The composition of the IZTO channel layer 45 can be controlled in detail by sputtering using different powers for each target. Specifically, the IZTO channel layer 45 may be formed to have a composition of Zn₂₋ₓSn₁₋ₓIn₂ₓO₄ (0<x<0.45). Here, the x value may be 0.3 to 0.36, for example, the x value may be 0.33. The IZTO channel layer 45 may be in an amorphous state immediately after being deposited. The IZTO channel layer 45 may be formed to have a thickness of several to tens of nm, for example, 10 to 50 nm, for example, 10 to 30 nm, which can be sufficiently crystallized through heat treatment to be described later.

A source electrode 50S and a drain electrode 50D may be formed on both ends of the IZTO channel layer 45, so that a portion of the surface of the IZTO channel layer 45 may be exposed between the source electrode 50S and the drain electrode 50D. The source electrode 50S and the drain electrode 50D may be formed using at least one metal selected from aluminum (Al), neodymium (Nd), silver (Ag), chromium (Cr), titanium (Ti), tantalum (Ta), and molybdenum (Mo) or an alloy containing the metal, or a metal oxide conductive film for example, ITO (Indium Tin Oxide).

A patterned capping layer 60 may be formed on the IZTO channel layer 45 exposed between the source electrode 50S and the drain electrode 50D. The capping layer 60 may be a layer containing a transition metal, and the transition metal contained therein is a transition metal with a higher oxidation tendency compared to the metal(s) contained in the IZTO channel layer 45, that is, In, Zn, and Sn. As an example, the capping layer may be a Ta layer, a Ti layer, or a Mo layer. As another example, the capping layer may be a transition metal nitride layer containing a small amount of nitrogen (e.g., a nitrogen content of 5 to 35 atomic percent), that is, a transition metal-rich transition metal nitride layer, for example, Ti-rich TiN. layer, a Ta-rich TaN layer, or a Mo-rich MoN layer.

Specifically, when the transition metal contained in the capping layer 60 is Ta, the Gibbs free energy (ΔGf) for forming Ta₂O₅ may be lower than all the Gibbs free energies for forming oxides of metals contained within the IZTO channel layer 45, that is, In oxide such as In₂O₃, Zn oxide such as ZnO, and Sn oxide such as SnO₂. In other words, Ta may have a greater oxidation tendency than In, Zn, and Sn.

The capping layer 60 may be formed to have a thickness of 3 to 30 nm, for example, 5 to 20 nm, specifically 7 to 15 nm. The ratio of the thickness of the IZTO channel layer 45 to the thickness of the capping layer 60 is 3:1 to 1:2, for example, 2.5:1 to 1:1 for uniform crystallization of the IZTO channel layer in the crystallization process described later.

In addition, the capping layer 60 may be formed to overlap the gate electrode 20 located below the IZTO channel layer 45, and specifically overlaps the center of the gate electrode 20 or the center of the channel region of the TFT. However, in this embodiment, the capping layer 60 may be formed so as not to contact the source/drain electrodes 50S and 50D by having a short length compared to the channel length of the TFT, that is, the spacing between the source/drain electrodes 50S and 50D. The capping layer 60 may have a width equal to or wider than the channel width of the TFT, that is, the width of the IZTO channel layer 45, so that crystallization described later can occur throughout the entire channel width of the IZTO channel layer 45.

After forming the capping layer 60, the resulting product may be subjected to heat treatment, specifically post-deposition annealing (PDA). The heat treatment may be performed in an oxygen atmosphere, in a temperature range of about 150° C. to 500° C., specifically more than about 250° C. and less than 400° C., more specifically about 270° C. to 350° C. or about 290° C. to 310° C.

During the heat treatment process, within a region of the IZTO channel layer 45 near the interface between the capping layer 60 and the IZTO channel layer 45, oxygen species loosely bound to metal atoms, for example, interstitial oxygen and hydroxyl groups can be removed or consumed by reacting with the metal in the capping layer 60 to form transition metal oxide (M^{a}Oₓ, M^{a} is a metal in the capping layer), and at the same time, as the transition metal oxide is formed within in the capping layer 60, electrons may be emitted into the IZTO channel layer 45. The electrons supplied into the IZTO channel layer 45 at the interface in contact with the capping layer 60 may be transferred to the antibonding orbital of the metal-oxygen bond in the IZTO channel layer 45, thereby weakening the metal-oxygen bond at the interface. In addition, during the crystallization annealing process, the metal-oxygen bond at the interface weakened may be broken and rearranged from the interface, and as this rearrangement may propagate inside the IZTO channel layer 45, the entire IZTO channel layer 45 may be converted to crystalline form at a relatively low temperature. As a result, the metal-oxygen lattice fraction in the IZTO channel layer 45 may increase compared to before heat treatment and the degree of crystallinity may also increase. Meanwhile, the degree of crystallinity in the IZTO channel layer 45 may decrease from the side in contact with the capping layer 60 toward the opposite side, that is, toward the gate insulating layer 30. In other words, the degree of crystallinity in the IZTO channel layer 45 may decrease toward the gate insulating layer 30 from the surface opposite to the surface in contact with the gate insulating layer 30.

During the heat treatment process, an ohmic contact may also be formed between the source/drain electrodes 50S and 50D and the IZTO channel layer 45.

Meanwhile, when the crystallization heat treatment is carried out in an oxygen atmosphere, the capping layer 60 may be oxidized not only at the interface in contact with the IZTO channel layer 45 but also at the surface exposed to the oxygen atmosphere, forming an insulating transition metal oxide layer (ex. Ta oxide layer, Ti oxide layer, or Mo oxide layer). After the crystallization heat treatment, the transition metal oxide layer may be removed by etching to expose the surface of the IZTO channel layer 45. However, it is not limited to this.

The crystallized IZTO channel layer 45 may have a spinel single-phase crystalline structure. The single crystal phase may mean that it includes a plurality of crystal grains, and the plurality of crystal grains all have the same crystal phase but have different crystal directions with respect to the reference plane. To elaborate, a plurality of crystal grains in the crystallized IZTO channel layer 45 may have the same spinel crystal phase, but the crystal directions of the crystal grains may vary. Additionally, the crystallized IZTO channel layer 45 may not have any other crystal phase other than the spinel crystal phase. As previously described, the IZTO channel layer 45 may have a composition of Zn₂₋ₓSn₁₋ₓIn₂ₓO₄ (0<x<0.45). Specifically, the x value may be 0.3 to 0.36, as an example, the x value may be 0.33. The crystallized IZTO channel layer 45 may have a plurality of crystal grains, and all the crystal grains may have a composition of Zn₂₋ₓSn₁₋ₓIn₂ₓO₄ (0<x<0.45). The crystallized IZTO channel layer 45 may have crystal planes of (220), (222), (331), and (422).

In order for the crystallized IZTO channel layer 45 to have a spinel single crystal phase structure, as described above, sputtering targets can be placed separately for each metal and the composition can be finely controlled by using different powers for each target. In addition, the IZTO channel layer 45 can have a spinel single crystal phase structure by crystallizing at a lower temperature through crystallization heat treatment using the capping layer 60.

FIG. 2 is a cross-sectional view showing a method of manufacturing a thin film transistor according to another embodiment of the present invention. The thin film transistor manufacturing method according to this embodiment may be similar to the thin film transistor manufacturing method described with reference to FIG. 1, except as described later.

Referring to FIG. 2, a gate electrode 20 extending in one direction may be formed on a substrate 10, and a gate insulating layer 30 may be formed on the gate electrode 20. A source electrode 50S and a drain electrode 50D may be formed on the gate insulating layer 30. At least a portion of the portion of the gate insulating layer 30 that overlaps the gate electrode 20 may be exposed between the source electrode 50S and the drain electrode 50D.

An IZTO channel layer covering the exposed gate insulating layer 30 and the source electrode 50S and drain electrode 50D may be formed using the method as described with reference to FIG. 1. Afterwards, a capping layer can be formed on the IZTO channel layer. Afterwards, the capping layer and the IZTO channel layer may be sequentially patterned to form a patterned IZTO channel layer 45 and a patterned capping layer 60 sequentially stacked on the gate insulating layer 30. As a result, the patterned IZTO channel layer 45 and the capping layer 60 may have substantially the same width and the same length. The IZTO channel layer 45 crosses the top of the gate electrode 20 and can be connected to the source electrode 50S and the drain electrode 50D at both ends. In other words, the source electrode 50S and the drain electrode 50D may be connected to the IZTO channel layer 45 below both ends of the IZTO channel layer 45.

After depositing the capping layer 60 but before patterning or after patterning the capping layer 60, the resulting product may be heat treated as described with reference to FIG. 1. During the crystallization heat treatment process, the IZTO channel layer 45 may be crystallized, as described with reference to FIG. 1.

Specifically, the crystallized IZTO channel layer 45 may have a spinel single-phase crystalline structure. A single crystal phase may mean that it includes a plurality of crystal grains, and the plurality of crystal grains all have the same crystal phase but have different crystal directions with respect to the reference plane. To elaborate, a plurality of crystal grains in the crystallized IZTO channel layer 45 have the same spinel crystal phase, but the crystal directions of the crystal grains may vary. The crystallized IZTO channel layer 45 may have a composition of Zn₂₋ₓSn₁₋ₓIn₂ₓO₄ (0<x<0.45). Specifically, the x value may be 0.3 to 0.36, for example, the x value may be 0.33.

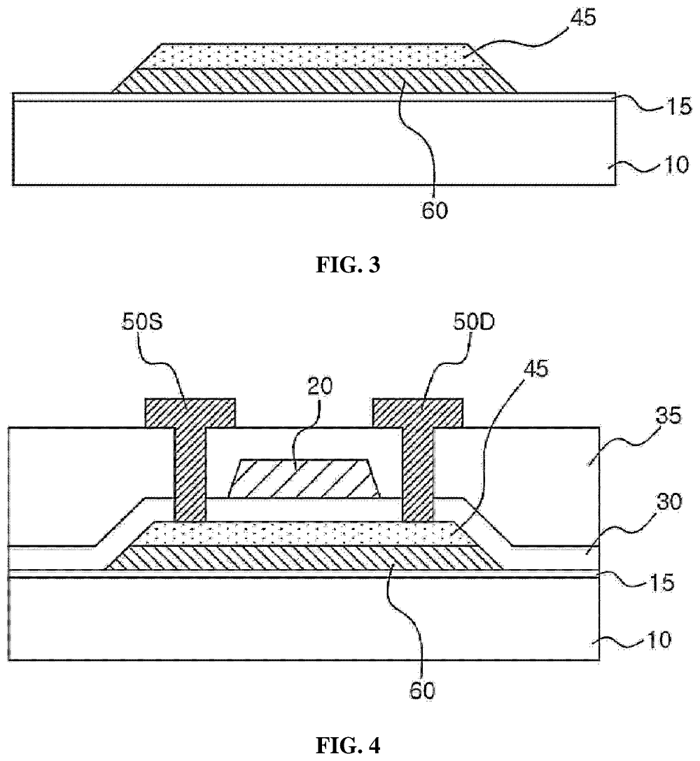

FIGS. 3 and 4 are cross-sectional views showing a method of manufacturing a thin film transistor according to another embodiment of the present invention. The thin film transistor manufacturing method according to this embodiment may be similar to the thin film transistor manufacturing method described with reference to FIG. 1, except as described later.

Referring to FIG. 3, a buffer layer 15 may be formed on the substrate 10. The buffer layer 15 may be a silicon oxide layer, a silicon oxynitride layer, a silicon nitride layer, or a composite layer thereof.

A capping layer and an IZTO channel layer are sequentially formed on the buffer layer 15, and the IZTO channel layer and the capping layer are sequentially patterned to form a patterned capping layer 60 and an IZTO channel layer 45 sequentially stacked on the buffer layer 15. As a result, the patterned IZTO channel layer 45 and the capping layer 60 may have substantially the same width and the same length.

When the IZTO channel layer is deposited and not patterned or in a patterned state, the resulting product can be subjected to crystallization heat treatment as described with reference to FIG. 1. Specifically, the crystallization heat treatment may be performed in a temperature range of about 150° C. to 500° C., specifically more than about 250° C. but less than 400° C., more specifically about 270° C. to 350° C. or about 290° C. to 310° C.

During the crystallization heat treatment process, the IZTO channel layer 45 may be crystallized, as described with reference to FIG. 1. Specifically, the crystallized IZTO channel layer 45 may have a spinel single-phase crystalline structure. Here, a single crystal phase may mean that it includes a plurality of crystal grains, and the plurality of crystal grains all have the same crystal phase but have different crystal directions with respect to the reference plane. To elaborate, a plurality of crystal grains in the crystallized IZTO channel layer 45 have the same spinel crystal phase, but the crystal directions of the crystal grains may vary. The crystallized IZTO channel layer 45 may have a composition of Zn₂₋ₓSn₁₋ₓIn₂ₓO₄ (0<x<0.45). Specifically, the x value may be 0.3 to 0.36, for example, the x value may be 0.33.

Referring to FIG. 4, a gate insulating layer 30 may be formed on the IZTO channel layer 45. A gate electrode 20 crossing the top of the IZTO channel layer 45 may be formed on the gate insulating layer 30. As a result, the IZTO channel layer 45 may be disposed under the gate electrode 20, overlapping with the gate electrode 20. Afterwards, an interlayer insulating film 35 covering the gate electrode 20 may be formed on the gate electrode 20. The interlayer insulating film 35 may be a silicon oxide film, a silicon oxynitride film, a silicon nitride film, or a composite film thereof.

Contact holes exposing both ends of the IZTO channel layer 45 may be formed in the interlayer insulating film 35 and the gate insulating film 30 below the interlayer insulating film 35. A source electrode 50S and a drain electrode 50D connected to both sides of the IZTO channel layer 45 may be formed in the contact holes, respectively. Afterwards, heat treatment to improve ohmic contact between the IZTO channel layer 45 and the source/drain electrodes 50S and 50D may be additionally performed. However, it is not limited to this, and in another embodiment, the above-described crystallization heat treatment may be performed after forming the source/drain electrodes 50S and 50D to crystallize the IZTO channel layer 45 and simultaneously improve ohmic contact between the IZTO channel layer 45 and the source/drain electrodes 50S and 50D.

The thin film transistors shown in FIGS. 1, 2, and 4 respectively represent a bottom gate/top contact structure, a bottom gate/bottom contact structure, and a top gate/top contact structure, but are not limited thereto and in another embodiment, a thin film transistor structure can also be implemented to have a top gate/bottom contact structure.

In addition, the n-type thin film transistor having the IZTO channel layer, which is an n-type semiconductor described above, together with the p-type thin film transistor, can form an inverter as an example of a complementary thin film transistor (TFT) circuit. The p-type thin film transistor may include a p-type oxide semiconductor as a channel layer, and the p-type oxide semiconductor may be SnO, Cu₂O, or NiO, but is not limited thereto.

In addition, the n-type thin film transistor can be used as a switching element electrically connected to the pixel electrode of an organic light-emitting diode (OLED) or liquid crystal display; or can also be used as a switching element electrically connected to one electrode of a memory element, such as resistance change memory (RRAM), phase change RAM (PRAM), or MRAM (magnetic RAM). However, it is not limited to this.

A preferred experimental example is presented to aid understanding of the present invention. However, the following experimental examples are only intended to aid understanding of the present invention, and the present invention is not limited by the following experimental examples.

### TFT Preparation Example 1

A p-type Si wafer (<0.005 Ω·cm), which is a gate electrode, was thermally oxidized to grow a 100 nm SiO₂ layer, which is a gate insulating layer, on the p-type Si wafer. A shadow mask was placed on the SiO₂ layer, and an amorphous IZTO semiconductor pattern with a thickness of 20 nm was deposited using RF magnetron sputtering at room temperature. During sputtering, the chamber maintained a pressure of 3 mTorr under Ar 10 sccm; three targets of an indium oxide (In₂O₃) target, a zinc oxide (ZnO) target, and a tin oxide (SnO₂) target were used; and the targets were sputtered at a power of 70 w, 130 w, and 45 w, respectively.

A shadow mask was placed on the amorphous IZTO semiconductor pattern and an ITO pattern was deposited using sputtering in an Ar atmosphere to form source/drain electrodes on both ends of the IZTO semiconductor pattern. The width of each of the source/drain electrodes was 1000 μm, and the exposed length of the semiconductor pattern between the source/drain electrodes was 300 μm.

On the semiconductor pattern exposed between the source/drain electrodes, a 10 nm Ta layer was formed by sputtering (Ar 10 sccm/2 m Torr/100 w conditions) using a shadow mask. The width of the Ta layer was 2300 μm, which was wider than the width of the source/drain electrodes, and the length of the Ta layer was 150 μm, which was shorter than the length of the semiconductor pattern exposed between the source/drain electrodes.

Afterwards, post-deposition annealing (PDA) was performed at 300° C. for 1 hour in an O₂ atmosphere.

### TFT Preparation Example 2

A TFT was prepared in the same manner as in TFT Preparation Example 1, except that post-deposition annealing (PDA) was performed at 200° C. for 1 hour in an O₂ atmosphere.

### TFT Preparation Examples 3 to 5

TFTs were prepared in the same manner as in TFT Preparation Example 1, except that, without forming the Ta layer and with the semiconductor pattern exposed between the source/drain electrodes, the post-deposition annealing (PDA) was performed in an O₂ atmosphere at 400° C. (Preparation Example 3), 700° C. (Preparation Example 4), or 800° C. (Preparation Example 5) for 1 hour.

### Metal Oxide Thin Film Preparation Examples 1 to 3

A p-type Si wafer (<0.005 Ω·cm) was thermally oxidized to grow a 100 nm SiO₂ layer. An amorphous IZTO semiconductor pattern with a thickness of 20 nm was deposited on the SiO₂ layer using RF magnetron sputtering at room temperature. The target during sputtering was a target having a spinel single crystal phase of Zn₂SnO₄ with a molar ratio of ZnO and SnO₂ of 2:1, and the sputtering chamber was maintained at a pressure of 3 mTorr, and the sputtering was carried out under gas flow conditions as shown in Table 1 below.

### Metal Oxide Thin Film Preparation Example 4

A 10 nm Ta layer was formed on the metal oxide thin film according to Metal Oxide Thin Film Preparation Example 1 by sputtering, and post-deposition annealing (PDA) was performed at 300° C. for 1 hour in an O₂ atmosphere to prepare a metal oxide thin film.

### Metal Oxide Thin Film Preparation Examples 5 to 7

With the metal oxide thin film according to Metal Oxide Thin Film Preparation Example 1 exposed, post-deposition annealing (PDA) was performed at 400° C. (Preparation Example 5), 700° C. (Preparation Example 6), or 800° C. (Preparation Example 7) in an air atmosphere for 1 hour to prepare a metal oxide thin film.

Table 1 below shows the process conditions according to Metal Oxide Thin Film Preparation Examples 1 to 3 and the composition of the resulting metal oxide thin film.

TABLE 1

| | | Gas Flow | Metal Oxide Thin | |
|---|---|---|---|---|
| | | Conditions during | Film Composition | |
| | Sputtering | Sputtering Ar:O₂ | Zn | Sn |
| | Target | (V:V) | (at %) | (at %) |
| Metal Oxide Thin Film | Zn₂SnO₄ | 10:0 | 61.9 | 38.1 |
| Preparation Example 1 | | | | |
| Metal Oxide Thin Film | | 9:1 | 58.6 | 41.4 |
| Preparation Example 2 | | | | |
| Metal Oxide Thin Film | | 8:2 | 57.8 | 42.2 |
| Preparation Example 3 | | | | |

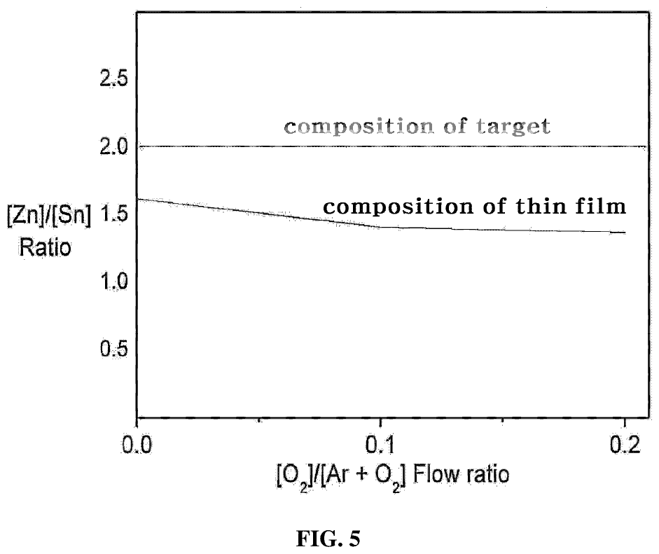

FIG. 5 is a graph showing the composition of the metal oxide thin films obtained from Metal Oxide Thin Film Preparation Examples 1 to 3 according to gas flow conditions during sputtering. Referring to Table 1 and FIG. 5, even when only Ar gas was used during sputtering, the target and the obtained thin film showed different Zn/Sn atomic ratios. Additionally, when the flow rate of oxygen increased relative to the flow rate of Ar, the difference in composition of the Zn/Sn atomic ratio between the target and the obtained thin film became larger. This was assumed to be because the binding energy of Zn—O was greater than that of Sn—O. Referring to this, the composition of the thin film obtained by sputtering may not necessarily be the same as the composition of the target, and the composition of the target and the composition of the thin film may vary depending on the mass of the metal in the target and the difference in the chemical bond between the metal and oxygen.

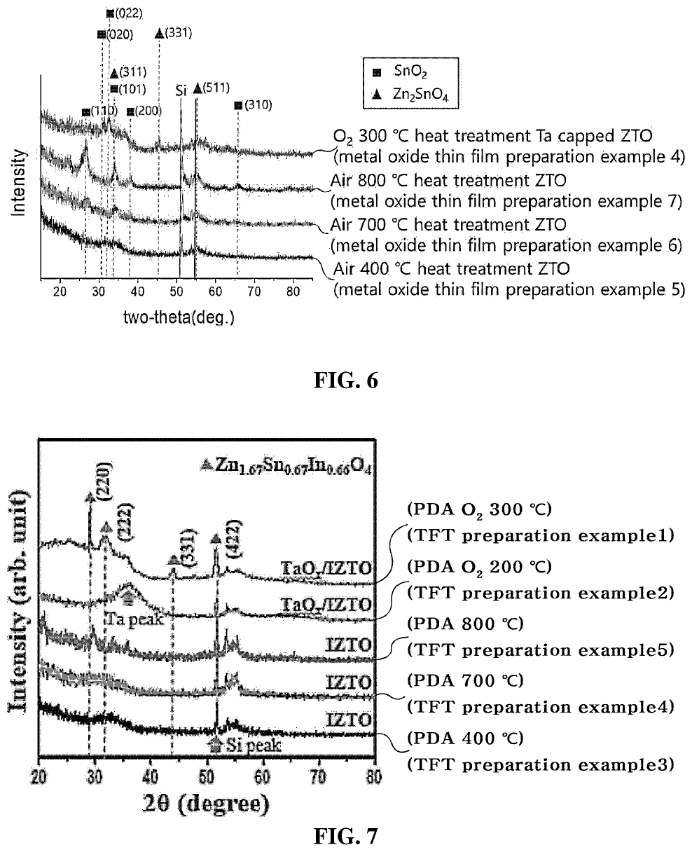

FIG. 6 is a graph showing XRD patterns of metal oxide thin films according to Metal Oxide Thin Film Preparation Examples 4 to 7.

Referring to FIG. 6, the thin film heat-treated at 400° C. in an air atmosphere obtained from Metal Oxide Thin Film Preparation Example 5 was in an amorphous state without crystallization. The thin films heat-treated at 700° C. and 800° C. in an air atmosphere respectively obtained from Metal Oxide Thin Film Preparation Examples 6 and 7 were crystallized, and both have cubic spinel Zn₂SnO₄ crystal phase and tetragonal SnO₂ crystal phase, but the intensity of each peak was greater in the thin film heat-treated at 800° C. obtained from Metal Oxide Thin Film Preparation Example 7. Meanwhile, the thin film heat-treated at 300° C. in an 02 atmosphere after forming a Ta capping layer obtained from Metal Oxide Thin Film Preparation Example 4 was crystallized even at a low temperature, showing a cubic spinel Zn₂SnO₄ crystal phase and an orthorhombic SnO₂ crystal phase.

As described above, the metal oxide thin films obtained from Metal Oxide Thin Film Preparation Examples 4, 6, and 7 were manufactured using a sputtering target of the same composition, that is, a target having a single spinel crystal phase of Zn₂SnO₄, but the metal oxide thin films obtained from Metal Oxide Thin Film Preparation Examples 6 and 7 underwent post-deposition annealing (PDA) under conditions of 700° C. or higher in an air atmosphere without a Ta capping layer show a cubic spinel Zn₂SnO₄ crystal phase as well as a tetragonal SnO₂ crystal phase, whereas the metal oxide thin film obtained from Metal Oxide Thin Film Preparation Example 4 underwent post-deposition annealing (PDA) under conditions of 300° C. in O₂ atmosphere after forming the Ta capping layer shows a cubic spinel Zn₂SnO₄ crystal phase and an orthorhombic SnO₂ crystal phase. Therefore, even if thin films are formed using a sputtering target of the same composition, the crystal phases may be different due to the difference in the annealing process.

FIG. 7 is a graph showing XRD patterns of IZTO semiconductor patterns included in TFTs manufactured in TFT Preparation Examples 1 to 5.

Referring to FIG. 7, when post-deposition annealing (PDA) was performed under conditions of 700° C. or lower in an air atmosphere without forming a Ta capping layer according to TFT Preparation Examples 3 and 4, no crystalline peak was visible. On the other hand, when the process was performed under conditions above 800° C. according to TFT Preparation Example 5, the spinel Zn_{1.67}Sn_{0.67}In_{0.66}O₄ crystal phase was confirmed. Meanwhile, when post-deposition annealing (PDA) is performed under conditions of 200° C. or less in an oxygen atmosphere with the Ta capping layer formed according to TFT Preparation Example 2, Ta is not completely oxidized, so the Ta peak is visible but the crystalline peak resulting from the IZTO semiconductor pattern was not visible. On the other hand, when the process was performed under conditions of 300° C. or higher according to TFT Preparation Example 1, the spinel Zn_{1.67}Sn_{0.67}In_{0.66}O₄ crystal phase resulting from the IZTO semiconductor pattern was confirmed.

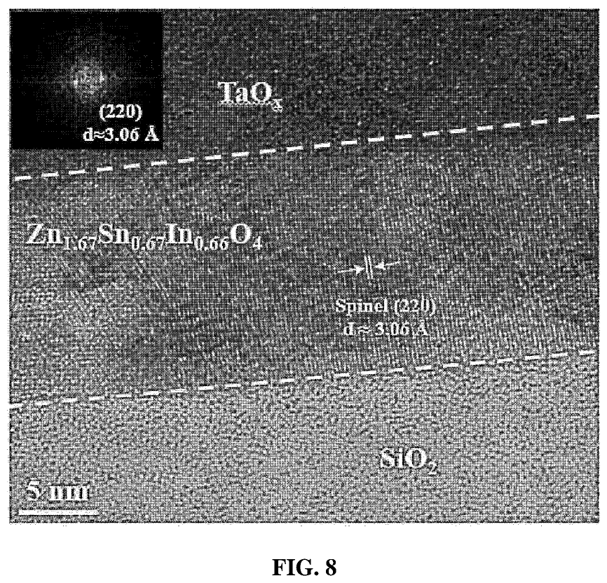

FIG. 8 is a TEM (Transmission Electron Microscope) image of a cross-section of the IZTO semiconductor pattern included in the TFT manufactured in TFT Preparation Example 1.

Referring to FIG. 8, the IZTO semiconductor pattern manufactured in TFT Preparation Example 1 was confirmed to have a (220) plane on the spinel crystal, and the interplanar distance was found to be 3.06 Å. It also shows that the angle formed by the direction of the (220) plane of the spinel crystal and the surface of the IZTO semiconductor pattern may vary depending on the location.

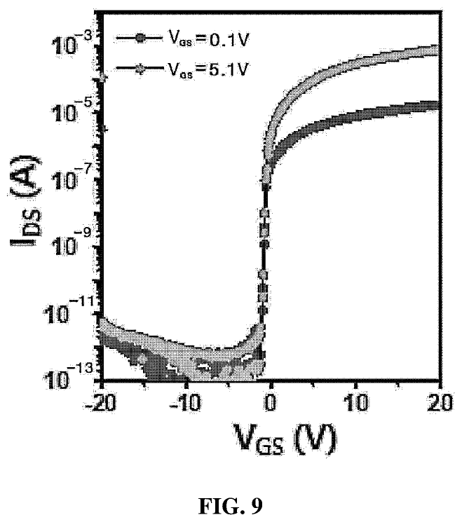

FIG. 9 is a graph showing the transfer characteristics of the TFT manufactured in TFT Preparation Example 1.

Referring to FIG. 9, the TFT manufactured in TFT Preparation Example 1 has a field-effect mobility (FE) of 86.55±5.3 cm²/Vs, SS (Subthreshold Swing) of 0.119±0.025 V/dec., threshold voltage (V_{TH}) of −0.13±0.23 V, hysteresis of 0.001, and interface trap density of 2.06×10¹¹/cm² eV.

As above, it can be seen that the thin film transistor with the IZTO channel layer having a single crystal phase of spinel has very excellent field-effect mobility and SS value.

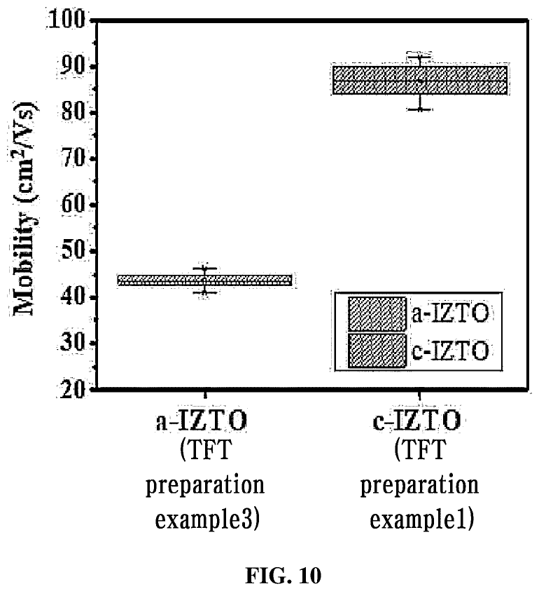

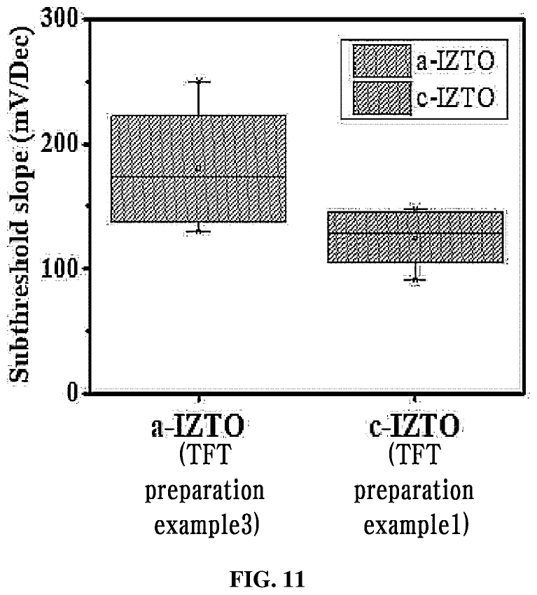

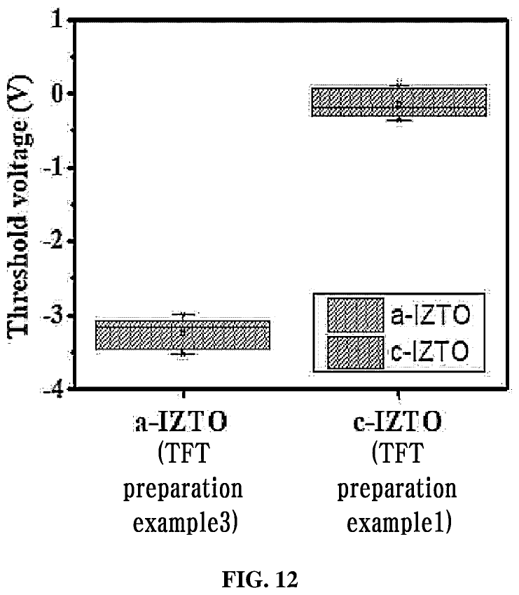

FIGS. 10, 11, and 12 are graphs showing the distribution of mobility, SS, and threshold voltage of TFTs according to TFT Preparation Example 1 and TFT Preparation Example 3, respectively. The distribution is indicated by measuring the mobility, SS, and threshold voltage of a plurality of TFTs formed in the substrate.

Referring to FIGS. 10, 11, and 12, compared to the TFT according to TFT Preparation Example 3, that is, the TFT having amorphous IZTO as a channel layer, the TFT according to TFT Preparation Example 1, that is, the TFT having the IZTO channel layer having a single crystalline phase of spinel, showed low dispersion in mobility, SS, and threshold voltage. It is an unexpected result that a TFT with an IZTO channel layer with a single crystalline phase of spinel shows better distribution than a TFT with an amorphous channel layer, which is generally known to show excellent distribution. This may mean that a TFT having an IZTO channel layer with a single crystalline phase of spinel can be used in large-area displays or semiconductor manufacturing.

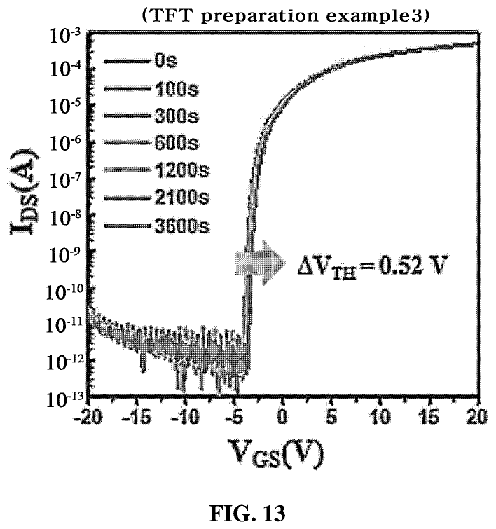

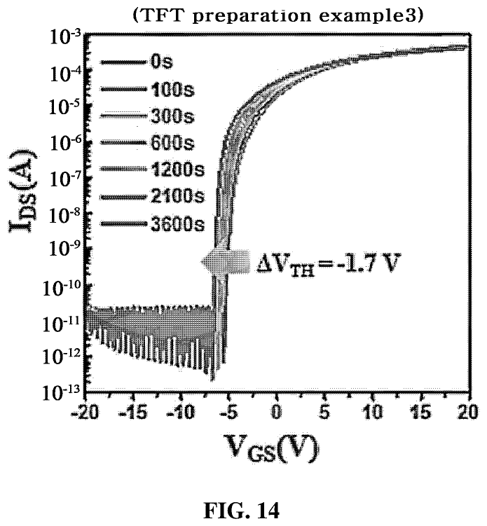

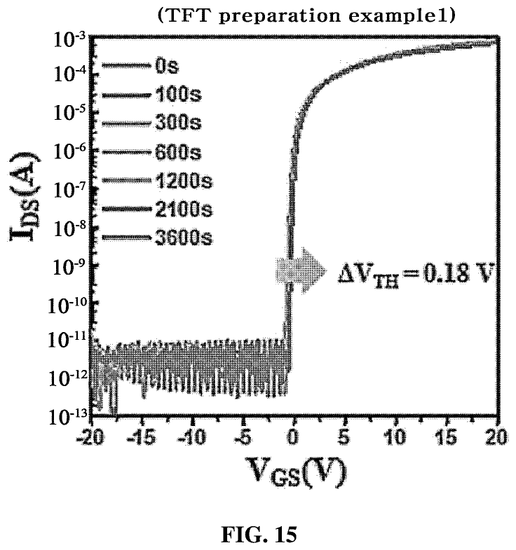

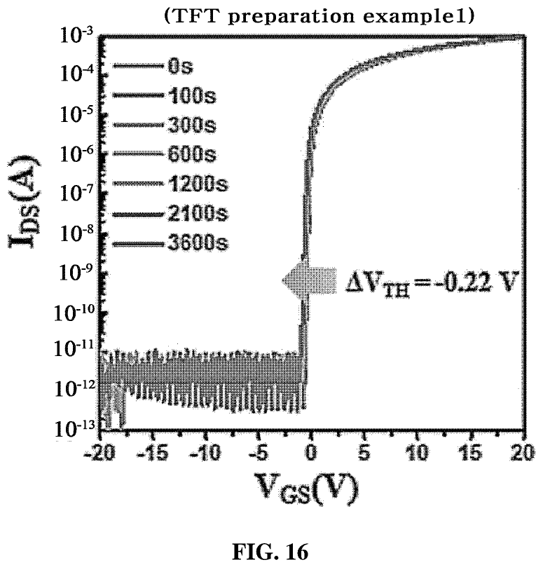

FIGS. 13 and 14 show the transfer characteristics of the TFT according to TFT Preparation Example 3 under positive gate bias stress (PBS) conditions and under negative gate bias stress (NBS) conditions, respectively. FIGS. 15 and 16 show the transfer characteristics of the TFT according to TFT Preparation Example 1 under positive gate bias stress (PBS) conditions and under negative gate bias stress (NBS) conditions, respectively. Positive gate bias stress (PBS) was applied for the indicated times at a gate bias of V_{TH}+20 V and a drain bias of 5.1 V. Negative gate bias stress (NBS) was applied for the indicated times at a gate bias of V_{TH}−20 V and a drain bias of 5.1 V.

Referring to FIGS. 13, 14, 15, and 16, even under positive gate bias stress (PBS) or negative gate bias stress (NBS), the TFT according to TFT Preparation Example 1 shows a smaller V_{TH} change compared to the TFT according to TFT Preparation Example 3. This excellent gate bias stress stability was understood to be due to crystallization.

While the exemplary embodiments of the present invention have been described above, those of ordinary skill in the art should understood that various changes, substitutions and alterations may be made herein without departing from the spirit and scope of the present invention as defined by the following claims.

1. A thin film transistor comprising:
a gate electrode;
an In—Zn—Sn oxide (IZTO) channel layer that overlaps the top or bottom of the gate electrode and has a spinel single-phase crystalline;
a gate insulating layer disposed between the gate electrode and the IZTO channel layer; and
source and drain electrodes respectively connected to both ends of the IZTO channel layer.

2. The thin film transistor of claim 1, wherein the IZTO channel layer includes a plurality of crystal grains having the same spinel crystal phase with different crystal directions.

3. The thin film transistor of claim 1, wherein the IZTO channel layer has a composition of Zn₂₋ₓSn₁₋ₓIn₂ₓO₄ (0<x<0.45).

4. The thin film transistor of claim 3, wherein the x is 0.3 to 0.36.

5. The thin film transistor of claim 4, wherein the x is 0.33.

6. The thin film transistor of claim 1, wherein the IZTO channel layer has crystal planes of (220), (222), (331), and (422).

7. A thin film transistor comprising:
a gate electrode;
an IZTO (In—Zn—Sn oxide) channel layer that overlaps the gate electrode and has a plurality of crystal grains, where all the crystal grains have a composition of Zn₂₋ₓSn₁₋ₓIn₂ₓO₄ (0<x<0.45);
a gate insulating layer disposed between the gate electrode and the IZTO channel layer; and
source and drain electrodes respectively connected to both ends of the IZTO channel layer.

8. The thin film transistor of claim 7, wherein the crystal grains has different crystal directions.

9. The thin film transistor of claim 7, wherein the x is 0.3 to 0.36.

10. The thin film transistor of claim 9, wherein the x is 0.33.

11. The thin film transistor of claim 7, wherein the IZTO channel layer has crystal planes of (220), (222), (331), and (422).
